(19) United States
(12) Patent Application Publication
(10) Pub. No.: US 2021/0332471 A1
(43) Pub. Date: Oct. 28, 2021

(54) Evaporation Device

(71) Applicant: WUHAN CHINA STAR OPTOELECTRONICS SEMICONDUCTOR DISPLAY TECHNOLOGY CO., LTD., Wuhan, Hubei (CN)

(72) Inventor: Chao XU, Wuhan, Hubei (CN)

(21) Appl. No.: 16/469,156

(22) PCT Filed: Nov. 16, 2018
(86) PCT No.: PCT/CN2018/115838

§ 371 Date: Jun. 13, 2019

(30) Foreign Application Priority Data
Oct. 17, 2018 (CN) 201811206219.1

(51) Int. Cl. C23C 14/24; C23C 14/54

(52) U.S. Cl. CPC C23C 14/243; C23C 14/246; C23C 14/54

(57) ABSTRACT

An evaporation device includes a primary chamber and two or more secondary chambers at both sides of the primary chamber. The secondary chamber is configured to supply the disposition material in a disposition process. One or more of the secondary chambers serve as an alternative disposition source. When the disposition material in one or more of the secondary chambers is nearly empty, the alternative disposition source in the other secondary chamber starts to operate.

### BACKGROUND

### 1. Field of the Disclosure

The present disclosure relates to a field of manufacturing a panel, and more particularly, to an evaporation device.

### 2. Description of the Related Art

The main fabrication of an organic light-emitting diode (OLED) device is to heat an evaporation coating.

A chamber is opened to feed the evaporation material to the evaporation device whenever the evaporation material is nearly consumed. The evaporation device is a high vacuum coating device so the working pressure needs to be less than 5*10−5 pascal (Pa). It takes one to two days to reduce the working pressure in the evaporation source, and it spends longer time to feed the evaporation material each time, which limits the productivity of the evaporation device.

Therefore, it is necessary to propose a new evaporation device to deal with the above problems.

### SUMMARY

The present disclosure proposes an evaporation device to solve the problem that the productivity of the evaporation device of the related art is reduced due to feeding.

According to a first aspect of the present disclosure, an evaporation device includes a primary chamber, two or more secondary chambers, a switch, and two or more first channels. The primary chamber includes a first shell, a platform arranged in the first shell, and a line source crucible arranged opposite to the platform. The two or more secondary chambers include a disposition source. The switch controls to turn on or off the secondary chamber or the disposition source. The first channel includes a first portion and a second portion. The first portion is arranged in the primary chamber. The second portion is arranged in the secondary chamber. The line source crucible is connected to the disposition source through the first channel.

According to an embodiment of the present disclosure, one or more first switch and second switch are arranged on each of the first channels. The first switch is arranged on the first portion, and the second switch is arranged on the second portion.

According to an embodiment of the present disclosure, the line source crucible comprises a second shell and a first hole on the second shell.

According to an embodiment of the present disclosure, the line source crucible further comprises one or more airflow dispersion plate arranged in the second shell and a second hole arranged on the airflow dispersion plate.

According to an embodiment of the present disclosure, the aperture of the first hole is not less than the aperture of the second hole.

According to an embodiment of the present disclosure, the evaporation device comprises one or more first secondary chamber and second secondary chamber. The evaporation source in the first secondary chamber and the second secondary chamber is connected to one or more of the first channels.

According to an embodiment of the present disclosure, a heating device is arranged on one or more of the surface of the line source crucible, the surface of the evaporation source, or the surface of the first channel.

According to an embodiment of the present disclosure, the heating device is a heating wire.

According to an embodiment of the present disclosure, the platform comprises a first opening. The pitch of the first opening in a first direction is less than the length of the substrate in the first direction.

According to a second aspect of the present disclosure, an evaporation device includes a primary chamber, two or more secondary chambers, a switch, two or more first channels, one or more first monitoring device, and one or more second monitoring device. The primary chamber includes a first shell, a platform arranged in the first shell, and a line source crucible arranged opposite to the platform. The two or more secondary chambers include a disposition source. The switch controls to turn on or off the secondary chamber or the disposition source. The first channel includes a first portion and a second portion. The first portion is arranged in the primary chamber. The second portion is arranged in the secondary chamber. The line source crucible is connected to the disposition source through the first channel. The one or more first monitoring device are arranged within the secondary chamber. The first monitoring device is configured to monitor the remaining amount of evaporation material in the disposition source. The one or more second monitoring device are arranged within the primary chamber. The second monitoring device configured to monitor the evaporating rate of the evaporation material.

According to an embodiment of the present disclosure, one or more first switch and second switch are arranged on each of the first channels. The first switch is arranged on the first portion, and the second switch is arranged on the second portion.

According to an embodiment of the present disclosure, the line source crucible comprises a second shell and a first hole on the second shell.

According to an embodiment of the present disclosure, the line source crucible further comprises one or more airflow dispersion plate arranged in the second shell and a second hole arranged on the airflow dispersion plate.

According to an embodiment of the present disclosure, the aperture of the first hole is not less than the aperture of the second hole.

According to an embodiment of the present disclosure, the evaporation device comprises one or more first secondary chamber and second secondary chamber. The evaporation source in the first secondary chamber and the second secondary chamber is connected to one or more of the first channels.

According to an embodiment of the present disclosure, a heating device is arranged on one or more of the surface of the line source crucible, the surface of the evaporation source, or the surface of the first channel.

According to an embodiment of the present disclosure, the heating device is a heating wire.

According to an embodiment of the present disclosure, the platform comprises a first opening. The pitch of the first opening in a first direction is less than the length of the substrate in the first direction.

The present disclosure proposes a disposition device which includes a primary chamber and two or more secondary chambers arranged on both sides of the primary chamber. The secondary chamber is configured to supply the disposition material in a disposition process. One or more of the secondary chambers serve as an alternative disposition source. When the disposition material in one or more of the secondary chambers is nearly empty, the alternative disposition source in the other secondary chamber starts to operate. The evaporation device can be continuously coated, which increases the productivity of the evaporation device. Besides, the maintenance time of the evaporation device is reduced.

### BRIEF DESCRIPTION OF THE DRAWINGS

The accompanying drawings described herein are used to provide further comprehension of the present disclosure, and is a part of the present application. Schematic embodiments of the present disclosure and the description thereof are used to illustrate the present disclosure, but do not constitute any improper limit to the present disclosure. In the accompanying drawings:

FIG. 1 is a schematic diagram of an evaporation device according to an embodiment of the present disclosure.

### DETAILED DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the FIGURES. It will be understood that the spatially relative terms are intended to encompass different orientations of the device in use or operation in addition to the orientation depicted in the FIGURES.

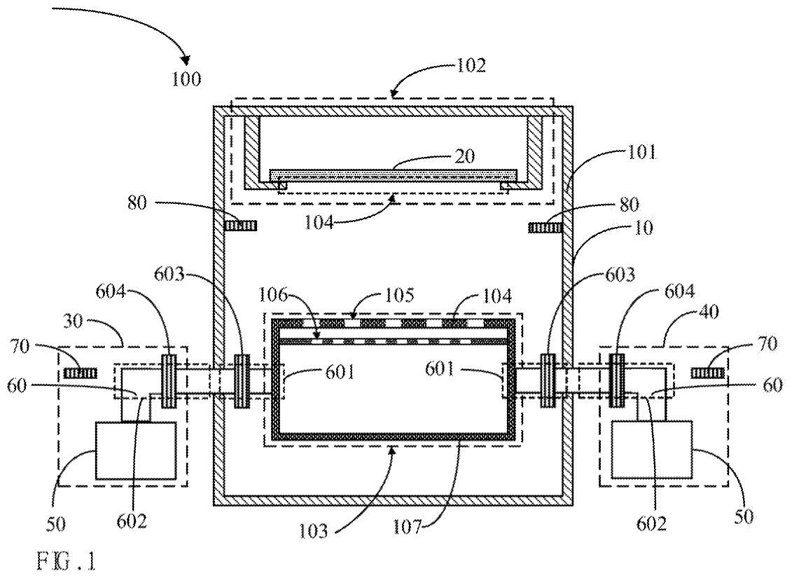

Please refer to FIG. 1 illustrating a schematic diagram of an evaporation device according to an embodiment of the present disclosure.

The evaporation device 100 includes a primary chamber 10 and two or more secondary chambers arranged around the primary chamber 10.

The primary chamber 10 includes a first shell 101, a platform 102 arranged in the first shell 101, and a line source crucible 103 arranged opposite the platform 102.

The platform 102 is configured to mount target substrates 20. Each of the target substrates 20 is marked and aligned before evaporation to reduce evaporation errors.

Please refer to FIG. 1. The platform 102 includes a first opening 105. The pitch of the first opening 105 in the horizontal direction is less than the length of the substrate 20 in the horizontal direction to connect the target substrate 20 to the platform 102. The area of the first opening 105 is the region where the target substrate 20 is deposited.

The platform 102 may further include an adsorption device. The adsorption device fixes the target substrate 20 by adsorption. Compared with an embodiment in which the first opening 105 is formed, the area in which the target substrate 20 is deposited is increased to reduce the waste of materials in the present embodiment.

Please refer to FIG. 1. The line source crucible 103 includes a second shell 104 and a first hole 105 arranged on the second shell 104.

The line source crucible 103 may include a plurality of first holes 105. The arrangement, number, shape and size of the first hole 105 are not specifically limited and can be determined according to actual needs.

The plurality of first holes 105 are distributed in an array on the first shell 101, and each of the first holes 105 is equal in size and shape.

In another embodiment, the first hole 105 may be cylindrical.

The line source port 103 further includes a primary switch (not shown) on the second shell 104. The primary switch is configured to control to turn on or off the line source crucible 103. It can also be understood that the primary switch is configured to control the termination or operation of the evaporation process.

In another embodiment, a primary switch may be arranged in parallel with a first opening 105.

The line source crucible 103 further includes one or more airflow dispersion plates 107 arranged in the second shell 104 and a second hole 106 arranged on the airflow dispersion plate 107. The airflow dispersion plate 107 is configured to uniformly release the evaporation material generated by the evaporation source 50, thereby ensuring the uniformity of the evaporation coating of the target substrate 20.

In another embodiment, the density of a second hole 106 on an airflow dispersion plate 107 near a platform 102 is not less than the density of the hole 106 on the airflow dispersion plate 107 away from the platform 102.

In another embodiment, the aperture of a second hole 106 on an airflow dispersion plate 107 near a platform 102 is not less than the aperture of the second hole 106 on the airflow dispersion plate 107 away from the platform 102.

An airflow dispersion plate 107 is arranged in the line source crucible 103. The aperture of the second hole 106 on the airflow dispersion plate 107 is less than the aperture of the first hole 105 on the second shell 104.

The evaporation device 100 includes one or more first secondary chamber 30 and second secondary chamber 40. A evaporation source 50 is arranged in the first secondary chamber 30 and the second secondary chamber 40. The evaporation source 50 is configured to produce the required evaporation material in the evaporation process.

In another embodiment, the evaporation material may be the organic material such as a luminescent material in an organic light-emitting diode (OLED) device.

The evaporation device 100 further includes two or more first channels 60 through which the line source crucible 103 is connected to the evaporation source 50. The first channel 60 includes a first portion 601 and a second portion 602. The first portion 601 is arranged in the primary chamber 10 and is connected to the line source crucible 103. The second portion 602 is arranged in the secondary chamber and is connected to the evaporation source 50 in the secondary chamber.

The evaporation device 100 further includes a plurality of switches arranged on the first channel 60 to control to turn on or off the secondary chamber or the evaporation source 50.

In another embodiment, one or more first switch 603 and second switch 604 are arranged on each of the first channels 60. The first switch 603 is arranged on the first portion 601, and the second switch 604 is arranged on the second portion 602. The first switch 603 is configured to control to turn on and off the line source crucible 103. The second switch 604 is configured to control to turn on and off the evaporation source 50.

The first switch 603 and the second switch 604 may be electromagnetic valves.

The evaporation source 50 in the first secondary chamber 30 and the second secondary chamber 40 is connected to one or more of the first channels 60. The specific quantity can be limited according to actual needs.

The evaporation source 50 further includes a heating device (not shown). The heating device is arranged on one or more of the surface of the line source crucible 103, the surface of the evaporation source 50, or the surface of the first channel 60.

The heating device is configured to increase the energy of the evaporation material and increase the rate of the evaporation in the evaporation process. Further, the evaporation material in the second shell 104 can be uniformly distributed with the heating device.

In another embodiment, a heating device is a heating wire. The heating wire is uniformly distributed on the surface of an evaporation source 50.

One or more first monitoring devices 70 are further arranged in the secondary chamber. The first monitoring device 70 is configured to monitor the remaining amount of the evaporation material in the evaporation source 50.

The first monitoring device 70 is a rate-monitoring device and configured to monitor the evaporating rate of the evaporation material in the secondary chamber to determine the remaining amount of the secondary material in the evaporation source 50.

The first monitoring device 70 is a weight-measuring device arranged at the bottom of the feeding area of the evaporation source 50. The first monitoring device 70 determines the remaining amount of the evaporation material in the evaporation source 50 by measuring the weight of the evaporation material.

One or more second monitoring device 80 is further arranged in the primary chamber 10. The second monitoring device 80 is configured to monitor the evaporating rate of the evaporation material.

Two of the second monitoring devices 80 arranged below the target substrate 20 are arranged in the primary chamber 10. The second monitoring device 80 is a rate-monitoring device and configured to monitor the evaporating rate of the evaporation material in the primary chamber 10 in real time and to assist to monitor the remaining amount of the evaporation material in the evaporation source 50. The second monitoring device 80 is further configured to monitor the uniformity of the distribution of the evaporation material in the primary chamber 10 to adjust the uniformity of film formation of the target substrate and to improve the quality of the product.

In the present disclosure, one or more of the secondary chambers are configured to be an alternative disposition source. The other secondary chamber is configured to be a working disposition source to ensure that the evaporation device is connected to the coating. Take the first secondary chamber as a working disposition source and the first secondary chamber as an alternative evaporation source for example.

When the first secondary chamber serves as a working evaporation source, the first switch and the second switch on the first channel connected to the first secondary chamber are in an open state and the first switch and the second switch on the second secondary chamber are in a closed state. When the first monitoring device arranged in the first secondary chamber monitors the evaporation material in the first secondary chamber to be almost empty, the second secondary chamber is in an active state. At the same time, the first secondary chamber is closed, and the first secondary chamber is stuffed with the material. Such an operation is cyclic.

The present disclosure proposes a disposition device which includes a primary chamber and two or more secondary chambers arranged on both sides of the primary chamber. The secondary chamber is configured to supply the disposition material in a disposition process. One or more of the secondary chambers serve as an alternative disposition source. When the disposition material in one or more of the secondary chambers is nearly empty, the alternative disposition source in the other secondary chamber starts to operate. The evaporation device can be continuously coated, which increases the productivity of the evaporation device. Besides, the maintenance time of the evaporation device is reduced.

Above are embodiments of the present disclosure, which does not limit the scope of the present disclosure. Any modifications, equivalent replacements or improvements within the spirit and principles of the embodiment described above should be covered by the protected scope of the invention.

What is claimed is:

1. A evaporation device, comprising:
a primary chamber, comprising a first shell, a platform arranged in the first shell, and a line source crucible arranged opposite to the platform;
two or more secondary chambers, comprising a disposition source;
a switch, configured to control to turn on or off the secondary chamber or the disposition source;
two or more first channels, the first channel comprising a first portion and a second portion; the first portion arranged in the primary chamber, the second portion arranged in the secondary chamber; the line source crucible connected to the disposition source through the first channel.

2. The evaporation device of claim 1, wherein one or more first switch and second switch are arranged on each of the first channels;
the first switch is arranged on the first portion; the second switch is arranged on the second portion.

3. The evaporation device of claim 1, wherein the line source crucible comprises a second shell and a first hole on the second shell.

4. The evaporation device of claim 3, wherein the line source crucible further comprises one or more airflow dispersion plate arranged in the second shell and a second hole arranged on the airflow dispersion plate.

5. The evaporation device of claim 4, wherein the aperture of the first hole is not less than the aperture of the second hole.

6. The evaporation device of claim 1, wherein the evaporation device comprises one or more first secondary chamber and second secondary chamber;
the evaporation source in the first secondary chamber and the second secondary chamber is connected to one or more of the first channels.

7. The evaporation device of claim 1, wherein a heating device is arranged on one or more of the surface of the line source crucible, the surface of the evaporation source, or the surface of the first channel.

8. The evaporation device of claim 7, wherein the heating device is a heating wire.

9. The evaporation device of claim 1, wherein the platform comprises a first opening;
the pitch of the first opening in a first direction is less than the length of the substrate in the first direction.

10. A evaporation device, comprising:
a primary chamber, comprising a first shell, a platform arranged in the first shell, and a line source crucible arranged opposite to the platform;
two or more secondary chambers, comprising a disposition source;
a switch, configured to control to turn on or off the secondary chamber or the disposition source;
two or more first channels, the first channel comprising a first portion and a second portion; the first portion arranged in the primary chamber, the second portion arranged in the secondary chamber; the line source crucible connected to the disposition source through the first channel;
one or more first monitoring device arranged within the secondary chamber; the first monitoring device configured to monitor the remaining amount of evaporation material in the disposition source;
one or more second monitoring device arranged within the primary chamber; the second monitoring device configured to monitor the evaporating rate of the evaporation material.

11. The evaporation device of claim 10, wherein one or more first switch and second switch are arranged on each of the first channels;
the first switch is arranged on the first portion; the second switch is arranged on the second portion.

12. The evaporation device of claim 10, wherein the line source crucible comprises a second shell and a first hole on the second shell.

13. The evaporation device of claim 12, wherein the line source crucible further comprises one or more airflow dispersion plate arranged in the second shell and a second hole arranged on the airflow dispersion plate.

14. The evaporation device of claim 13, wherein the aperture of the first hole is not less than the aperture of the second hole.

15. The evaporation device of claim 10, wherein the evaporation device comprises one or more first secondary chamber and second secondary chamber;
the evaporation source in the first secondary chamber and the second secondary chamber is connected to one or more of the first channels.

16. The evaporation device of claim 10, wherein a heating device is arranged on one or more of the surface of the line source crucible, the surface of the evaporation source, or the surface of the first channel.

17. The evaporation device of claim 16, wherein the heating device is a heating wire.

18. The evaporation device of claim 10, wherein the platform comprises a first opening;
the pitch of the first opening in a first direction is less than the length of the substrate in the first direction.
